(19) United States
(12) Patent Application Publication
(10) Pub. No.: US 2026/0112406 A1
(43) Pub. Date: Apr. 23, 2026

(54) Multi-die Memory Package with Individually Accessible Command/Address Pins

(71) Applicant: Advanced Micro Devices, Inc., Santa Clara, CA (US)

(72) Inventor: Aaron John Nygren, Boise, ID (US)

(73) Assignee: Advanced Micro Devices, Inc., Santa Clara, CA (US)

(21) Appl. No.: 19/312,390

(22) Filed: Aug. 28, 2025

Related U.S. Application Data
(60) Provisional application No. 63/709,655, filed on Oct. 21, 2024.

(51) Int. Cl. G11C 11/4093; G11C 11/4076; G11C 11/4096

(52) U.S. Cl. CPC G11C 11/4093; G11C 11/4076; G11C 11/4096

(57) ABSTRACT

A multi-die memory package with individually accessible command/address (CA) pins is described. In one or more implementations, a memory chip includes a plurality of memory dies arranged in a stacked configuration, a package substrate, and a plurality of command/address pins. Each command/address pin of the plurality of command/address pins is individually accessible via one or more corresponding interconnects to the package substrate or an intermediate component. The intermediate component may be configured to control use of the command/address pins and data pins at the memory chip level.

### RELATED APPLICATION

This application claims priority to U.S. Provisional Application Ser. No. 63/709,655, filed 21 Oct. 2024, titled “Multi-die Memory Package with Individually Connected Command/Address Pins for Use in Error Correction,” the disclosure of which is incorporated by reference herein in its entirety.

### BACKGROUND

Dual In-Line Memory Modules (DIMMs) are circuit boards that hold dynamic random-access memory (DRAM) chips, which serve as the memory for many computers. Over time, advancements in DIMM technology (e.g., DDR4 to DDR5)—such as increases in speed, higher data transfer rates, and larger storage capacities—have improved computer performance, enabling faster data processing, smoother multitasking, and support for memory-intensive applications like virtual machines, large-scale databases, and artificial intelligence workloads. These innovations can also contribute to energy efficiency, which reduces power consumption while delivering higher performance.

### BRIEF DESCRIPTION OF THE DRAWINGS

FIG. 1 is a block diagram of a processing system configured to execute one or more applications, in accordance with one or more implementations.

FIG. 2 is a block diagram of a non-limiting example of a memory system.

FIG. 3 is a block diagram of a non-limiting example of pins of multiple memory die of a memory chip, such as of a stacked DRAM.

FIG. 4 is a block diagram of a non-limiting example depicting how data (DQ) pins of multiple memory die of a memory chip are directly connected to a package substrate, in accordance with one or more implementations.

FIG. 5 is a block diagram of a non-limiting example depicting how command/address (CA) pins of multiple memory die of a memory chip are directly connected to a package substrate.

FIG. 6 depicts a prior art example of connecting command/address (CA) pins of a multi-die memory chip to package entry points.

FIG. 7 is a block diagram of a non-limiting example depicting how command/address (CA) pins of multiple memory die of a memory chip are directly connected to a die serving as a controller for the memory chip.

FIG. 8 is a block diagram of a non-limiting example depicting how command/address (CA) pins of multiple memory die of a memory chip are connected to a package substrate with through silicon vias and micro-bumps.

FIG. 9 is a block diagram of a non-limiting example depicting how command/address (CA) pins of multiple memory die of a memory chip are connected to a die serving as a controller for the memory chip with through silicon vias and micro-bumps.

FIG. 10 depicts a procedure in an example implementation of a multi-die memory package with individually connected command/address (CA) pins for use in error correction.

### DETAILED DESCRIPTION

In conventional memory systems, command/address (CA) pins may be interconnected between die using short bond wires. Additionally, traditional error correction code (ECC) implementations in memory modules (e.g., dual in-line memory modules (DIMMs)) typically allocate entire memory chips (DRAMs) to single subchannels, requiring memory manufacturers to produce non-standard chip configurations with odd numbers of die to support ECC functionality.

A multi-die memory package with individually accessible command/address (CA) pins is described. In accordance with the described techniques, the limitations of conventional approaches discussed above may be overcome by connecting each command/address pin (e.g., directly) to a package substrate, a memory die serving as a controller for the memory package, or externally at the printed circuit board level, e.g., using long bond wires. In one or more implementations, the memory package is a memory chip which includes a plurality of memory die arranged in a stacked configuration, a package substrate, and a plurality of command/address pins that are individually accessible via interconnects to the package substrate, an intermediate controller (e.g., a memory die serving as the controller for the memory chip), or externally..

This architecture enables greater flexibility in memory access configurations, allowing an individual memory chip to operate in various modes such as multiplexed (MUX) mode or error correcting code (ECC) mode. By providing individual connections to the package substrate, this approach improves signal integrity by eliminating the need for short bonds between dies. It also enhances memory bandwidth and system performance by allowing separate access to each memory rank within the multi-die package.

Furthermore, the described design supports more efficient ECC implementations. For example, the individually accessible data (DQ) pins and command/address (CA) pins enable the die of an individual memory chip to be split between multiple subchannels for handling ECC, allowing memory manufacturers to produce standard memory chips with power-of-two numbers of die while still supporting ECC functionality. By allowing memory manufacturers to use standard die configurations for both ECC and non-ECC applications, the described design also streamlines production processes. Overall, this approach provides improved performance, flexibility, and efficiency over conventional systems.

In some aspects, the techniques described herein relate to a memory chip, including: a package substrate; and a plurality of memory die arranged in a stacked configuration, the plurality of memory die having a plurality of command/address pins, wherein the plurality of command/address pins are individually accessible via interconnects to the package substrate or an intermediate controller.

In some aspects, the techniques described herein relate to a memory chip, wherein the interconnects are bond wires.

In some aspects, the techniques described herein relate to a memory chip, wherein the interconnects include through silicon vias and micro bumps.

In some aspects, the techniques described herein relate to a memory chip, wherein each command/address pin of the plurality of command/address pins is individually connected to the package substrate or the intermediate controller via a respective interconnect.

In some aspects, the techniques described herein relate to a memory chip, wherein the intermediate controller is a memory die of the plurality of memory die configured to control routing of commands and addresses to and from each of the plurality of command/address pins individually.

In some aspects, the techniques described herein relate to a memory chip, wherein the memory die is further configured to isolate command/address signals and handle clocking signals including at least one of data strobe (DQS), write clock (WCK), or clock (CK) signals.

In some aspects, the techniques described herein relate to a memory chip, wherein the plurality of command/address pins are individually controllable by a buffer external to the memory chip to enable the buffer to specify a type of a memory access and a location of the memory access in the memory chip.

In some aspects, the techniques described herein relate to a memory chip, further including a plurality of data pins, wherein the plurality of data pins are individually accessible via interconnects to the package substrate or the intermediate controller.

In some aspects, the techniques described herein relate to a memory chip, wherein the plurality of command/address pins are individually accessible to direct one or more data pins of the plurality of data pins to perform a type of a memory access at a location of the memory chip.

In some aspects, the techniques described herein relate to a memory chip, wherein the type of the memory access is a read access or a write access at the location of the memory chip.

In some aspects, the techniques described herein relate to a memory chip, wherein the plurality of command/address pins specify at least one of a row, column, or bank of the memory chip as the location for performing the memory access.

In some aspects, the techniques described herein relate to a memory chip, wherein the intermediate controller is a memory die of the plurality of memory die configured to control routing of: commands and addresses to and from each of the plurality of command/address pins individually; and data to and from each of the plurality of data pins individually.

In some aspects, the techniques described herein relate to a memory chip, wherein a first subset of command/address pins of the plurality of command/address pins are configured for use in a multiplexed mode of the memory chip and a second subset of command/address pins of the plurality of command/address pins are configured for use in an error correcting code mode of the memory chip.

In some aspects, the techniques described herein relate to a memory chip, wherein the memory chip is a dynamic random-access memory (DRAM) package and the plurality of memory die are DRAM die.

In some aspects, the techniques described herein relate to a method including: receiving a memory access request for a memory chip including a plurality of memory die arranged in a stacked configuration and having a plurality of command/address pins individually accessible via interconnects to a package substrate or an intermediate controller of the memory chip; and controlling, via the interconnects, one or more command/address pins of the plurality of command/address pins to direct one or more data pins of the memory chip to perform a type of memory access at a location of the memory chip to service the memory access request.

In some aspects, the techniques described herein relate to a method, wherein the memory access is a read access or a write access.

In some aspects, the techniques described herein relate to a method, wherein controlling the one or more command/address pins to direct the one or more data pins includes specifying at least one of a row, column, or bank of the memory chip as the location for performing the memory access.

In some aspects, the techniques described herein relate to a method, wherein a memory controller controls the one or more command/address pins to direct the one or more data pins to perform the type of the memory access at the location of the memory chip.

In some aspects, the techniques described herein relate to a computing system, including: a processor; and a memory system communicatively coupled to the processor to service memory access requests of the processor, wherein the memory system includes a memory chip including: a package substrate; and a plurality of memory die arranged in a stacked configuration, the plurality of memory die having a plurality of command/address pins, wherein the plurality of command/address pins are individually accessible via interconnects to the package substrate or an intermediate controller of the memory chip.

In some aspects, the techniques described herein relate to a computing system, wherein a first subset of command/address pins of the plurality of command/address pins are configured for use in a multiplexed mode of the memory chip to service the memory access requests of the processor and a second subset of command/address pins of the plurality of command/address pins are configured for use in an error correcting code mode of the memory system.

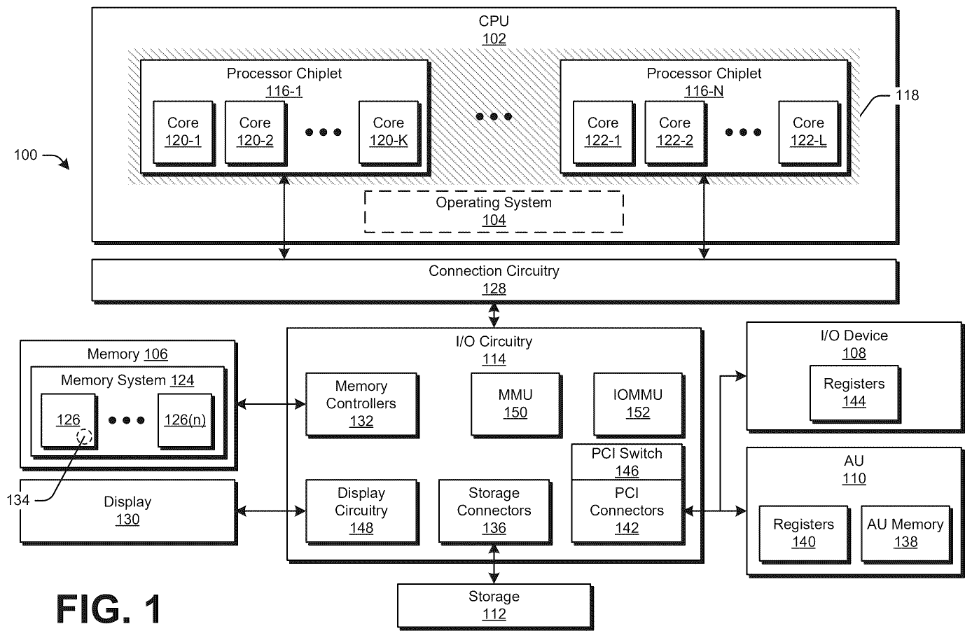

FIG. 1 is a block diagram of a processing system configured to execute one or more applications, in accordance with one or more implementations.

FIG. 1 includes a processing system 100 configured to execute one or more applications, such as compute applications (e.g., machine-learning applications, neural network applications, high-performance computing applications, databasing applications, gaming applications), graphics applications, and the like. Examples of devices in which the processing system is implemented include, but are not limited to, a server computer, a personal computer (e.g., a desktop or tower computer), a smartphone or other wireless phone, a tablet or phablet computer, a notebook computer, a laptop computer, a wearable device (e.g., a smartwatch, an augmented reality headset or device, a virtual reality headset or device), an entertainment device (e.g., a gaming console, a portable gaming device, a streaming media player, a digital video recorder, a music or other audio playback device, a television, a set-top box), an Internet of Things (IoT) device, an automotive computer or computer for another type of vehicle, a networking device, a medical device or system, and other computing devices or systems.

In the illustrated example, the processing system 100 includes a central processing unit (CPU) 102. In one or more implementations, the CPU 102 is configured to run an operating system (OS) 104 that manages the execution of applications. For example, the OS 104 is configured to schedule the execution of tasks (e.g., instructions) for applications, allocate portions of resources (e.g., system memory 106, CPU 102, input/output (I/O) device 108, accelerator unit (AU) 110, storage 112, I/O circuitry 114) for the execution of tasks for the applications, provide an interface to I/O devices (e.g., I/O device 108) for the applications, or any combination thereof.

The CPU 102 includes one or more processor chiplets 116, which are communicatively coupled together by a data fabric 118 in one or more implementations.

Each of the processor chiplets 116, for example, includes one or more processor cores 120, 122 configured to concurrently execute one or more series of instructions, also referred to herein as “threads,” for an application. Further, the data fabric 118 communicatively couples each processor chiplet 116-N of the CPU 102 such that each processor core (e.g., processor cores 120) of a first processor chiplet (e.g., 116-1) is communicatively coupled to each processor core (e.g., processor cores 122) of one or more other processor chiplets 116. Though the example embodiment presented in FIG. 1 shows a first processor chiplet (116-1) having three processor cores (120-1, 120-2, 120-K) representing a K number of processor cores 120 and a second processor chiplet (116-N) having three processor cores (e.g., 122-1, 122-2, 122-L) representing an L number of processor cores 122, in other implementations (L being an integer number greater than or equal to one), each processor chiplet 116 may have any number of processor cores 120, 122. For example, each processor chiplet 116 can have the same number of processor cores 120, 122 as one or more other processor chiplets 116, a different number of processor cores 120, 122 as one or more other processor chiplets 116, or both.

Examples of connections which are usable to implement data fabric include, but are not limited to, buses (e.g., a data bus, a system, an address bus), interconnects, memory channels, through silicon vias, traces, and planes. Other example connections include optical connections, fiber optic connections, and/or connections or links based on quantum entanglement.

In this example, the memory 106 is depicted with memory system 124, which is depicted with memory chips 126. In one or more implementations, the memory system 124 corresponds to a type of memory configured according to a standard, such as according to a JEDEC (Joint Electron Device Engineering Council) standard. Additionally or alternatively, the memory system 124 is a memory module, such as a dual in-line memory module (DIMM). In at least one example, for instance, the memory system 124 is a DIMM configured according to a JEDEC standard applicable to DIMMs, such as according to a double data rate # (DDR#) standard, where the ‘#’ symbol corresponds to an integer. In one or more implementations, the memory chips 126 are dynamic random-access memory (DRAM) chips, which are coupled to a printed circuit board forming the memory system 124. The memory system 124 is depicted with memory chip 126 and memory chip 126(n), where n represents any integer greater than or equal to 1. This represents that the memory system 124 is equipped with multiple memory chips 126 and may include various numbers of the memory chips 126. Although only one memory system 124 is depicted, in one or more implementations, the system 100 may include multiple memory systems 124, such as multiple memory systems 124 arranged in a stacked configuration. Additionally, or alternatively, multiple memory systems 124 arranged in a stack may also be arranged in a stack with one or more compute units, such as with one or more CPUs or GPUs and/or portions of a CPU or GPU, e.g., cores.

Additionally, within the processing system 100, the CPU 102 is communicatively coupled to an I/O circuitry 114 by a connection circuitry 128. For example, each processor chiplet 116 of the CPU 102 is communicatively coupled to the I/O circuitry 114 by the connection circuitry 128. The connection circuitry 128 includes, for example, one or more data fabrics, buses, buffers, queues, and the like. The I/O circuitry 114 is configured to facilitate communications between two or more components of the processing system 100 such as between the CPU 102, system memory 106, display 130, universal serial bus (USB) devices, peripheral component interconnect (PCI) devices (e.g., I/O device 108, AU 110), storage 112, and the like.

As an example, system memory 106 includes any combination of one or more volatile memories and/or one or more non-volatile memories, examples of which include dynamic random-access memory (DRAM), static random-access memory (SRAM), non-volatile RAM, and the like. To manage access to the system memory 106, such as by the CPU 102, the I/O device 108, the AU 110, and/or any other components, the I/O circuitry 114 includes one or more memory controllers 132. These memory controllers 132, for example, include circuitry configured to manage and fulfill memory access requests issued from the CPU 102, the I/O device 108, the AU 110, and/or any other device of the system. Examples of such requests include read requests, write requests, fetch requests, pre-fetch requests, and so on. That is to say, these memory controllers 132 are configured to manage access to the data stored at one or more memory addresses within the system memory 106, such as by CPU 102, the I/O device 108, and/or the AU 110. Although the memory controllers 132 are depicted separate from the memory system 124 in this example, in one or more implementations, one or more such memory controllers are included as part of the memory system 124, e.g., incorporated on or in or otherwise attached to the printed circuit board to which the memory chips 126 are mounted.

When an application is to be executed by processing system 100, the OS 104 running on the CPU 102 is configured to load at least a portion of program code 134 (e.g., an executable file) associated with the application from, for example, a storage 112 into system memory 106, such as into one or more memory chips 126 of the memory system 124. This storage 112, for example, includes a non-volatile storage such as a flash memory, solid-state memory, hard disk, optical disc, or the like, configured to store program code 134 for one or more applications.

To facilitate communication between the storage 112 and other components of processing system 100, the I/O circuitry 114 includes one or more storage connectors 136 (e.g., universal serial bus (USB) connectors, serial AT attachment (SATA) connectors, PCI Express (PCIe) connectors) configured to communicatively couple storage 112 to the I/O circuitry 114 such that I/O circuitry 114 is capable of routing signals to and from the storage 112 to one or more other components of the processing system 100.

In association with executing an application, in one or more scenarios, the CPU 102 is configured to issue one or more instructions (e.g., threads) to be executed for an application to the AU 110. The AU 110 is configured to execute these instructions by operating as one or more vector processors, coprocessors, graphics processing units (GPUs), general-purpose GPUs (GPGPUs), non-scalar processors, highly parallel processors, artificial intelligence (AI) processors (also known as neural processing units, or NPUs), inference engines, machine-learning processors, other multithreaded processing units, scalar processors, serial processors, programmable logic devices (e.g., field-programmable gate arrays (FPGAs)), or any combination thereof.

In at least one example, the AU 110 includes one or more compute units that concurrently execute one or more threads of an application and store data resulting from the execution of these threads in AU memory 138. This AU memory 138, for example, includes any combination of one or more volatile memories and/or non-volatile memories, examples of which include caches, video RAM (VRAM), or the like. In one or more implementations, these compute units are also configured to execute these threads based on the data stored in one or more physical registers 140 of the AU 110. Alternatively, or additionally, the AU 110 includes memory like the memory system 124, e.g., one or more memory modules.

To facilitate communication between the AU 110 and one or more other components of processing system 100, the I/O circuitry 114 includes or is otherwise connected to one or more connectors, such as PCI connectors 142 (e.g., PCIe connectors) each including circuitry configured to communicatively couple the AU 110 to the I/O circuitry such that the I/O circuitry 114 is capable of routing signals to and from the AU 110 to one or more other components of the processing system 100. Further, the PCIe connectors 142 are configured to communicatively couple the I/O device 108 to the I/O circuitry 114 such that the I/O circuitry 114 is capable of routing signals to and from the I/O device 108 to one or more other components of the processing system 100.

By way of example and not limitation, the I/O device 108 includes one or more keyboards, pointing devices, game controllers (e.g., gamepads, joysticks), audio input devices (e.g., microphones), touch pads, printers, speakers, headphones, optical mark readers, hard disk drives, flash drives, solid-state drives, and the like. Additionally, the I/O device 108 is configured to execute one or more operations, tasks, instructions, or any combination thereof based on one or more physical registers 144 of the I/O device 108. In one or more implementations, such physical registers 144 are configured to maintain data (e.g., operands, instructions, values, variables) indicating one or more operations, tasks, or instructions to be performed by the I/O device 108.

To manage communication between components of the processing system 100 (e.g., AU 110, I/O device 108) that are connected to PCI connectors 142, and one or more other components of the processing system 100, the I/O circuitry 114 includes PCI switch 146. The PCI switch 146, for example, includes circuitry configured to route packets to and from the components of the processing system 100 connected to the PCI connectors 142 as well as to the other components of the processing system 100. As an example, based on address data indicated in a packet received from a first component (e.g., CPU 102), the PCI switch 146 routes the packet to a corresponding component (e.g., AU 110) connected to the PCI connectors 142.

Based on the processing system 100 executing a graphics application, for instance, the CPU 102, the AU 110, or both are configured to execute one or more instructions (e.g., draw calls) such that a scene including one or more graphics objects is rendered. After rendering such a scene, the processing system 100 stores the scene in the storage 112, displays the scene on the display 130, or both. The display 130, for example, includes a cathode-ray tube (CRT) display, liquid crystal display (LCD), light emitting diode (LED) display, organic light emitting diode (OLED) display, or any combination thereof. To enable the processing system 100 to display a scene on the display 130, the I/O circuitry 114 includes display circuitry 148. The display circuitry 148, for example, includes high-definition multimedia interface (HDMI) connectors, DisplayPort connectors, digital visual interface (DVI) connectors, USB connectors, and the like, each including circuitry configured to communicatively couple the display 130 to the I/O circuitry 114. Additionally or alternatively, the display circuitry 148 includes circuitry configured to manage the display of one or more scenes on the display 130 such as display controllers, buffers, memory, or any combination thereof.

Further, the CPU 102, the AU 110, or both are configured to concurrently run one or more virtual machines (VMs), which are each configured to execute one or more corresponding applications. To manage communications between such VMs and the underlying resources of the processing system 100, such as any one or more components of processing system 100, including the CPU 102, the I/O device 108, the AU 110, and the system memory 106, the I/O circuitry 114 includes memory management unit (MMU) 146 and input-output memory management unit (IOMMU) 148. The MMU 150 includes, for example, circuitry configured to manage memory requests, such as from the CPU 102 to the system memory 106. For example, the MMU 150 is configured to handle memory requests issued from the CPU 102 and associated with a VM running on the CPU 102. These memory requests, for example, request access to read, write, fetch, or pre-fetch data residing at one or more virtual addresses (e.g., guest virtual addresses) each indicating one or more portions (e.g., physical memory addresses) of the system memory 106. Based on receiving a memory request from the CPU 102, the MMU 150 is configured to translate the virtual address indicated in the memory request to a physical address in the system memory 106 and to fulfill the request. The IOMMU 152 includes, for example, circuitry configured to manage memory requests (memory-mapped I/O (MMIO) requests) from the CPU 102 to the I/O device 108, the AU 110, or both, and to manage memory requests (direct memory access (DMA) requests) from the I/O device 108 or the AU 110 to the system memory 106. For example, to access the registers 144 of the I/O device 108, the registers 140 of the AU 110, and/or the AU memory 138, the CPU 102 issues one or more MMIO requests. Such MMIO requests each request access to read, write, fetch, or pre-fetch data residing at one or more virtual addresses (e.g., guest virtual addresses) which each represent at least a portion of the registers 144 of the I/O device 108, the registers 140 of the AU 110, or the AU memory 138, respectively. As another example, to access the system memory 106 without using the CPU 102, the I/O device 108, the AU 110, or both are configured to issue one or more DMA requests. Such DMA requests each request access to read, write, fetch, or pre-fetch data residing at one or more virtual addresses (e.g., device virtual addresses) which each represent at least a portion of the system memory 106. Based on receiving an MMIO request or DMA request, the IOMMU 152 is configured to translate the virtual address indicated in the MMIO or DMA request to a physical address and fulfill the request.

In variations, the processing system 100 can include any combination of the components depicted and described. For example, in at least one variation, the processing system 100 does not include one or more of the components depicted and described in relation to FIG. 1. Additionally, or alternatively, in at least one variation, the processing system 100 includes additional and/or different components from those depicted. The processing system 100 is configurable in a variety of ways with different combinations of components in accordance with the described techniques.

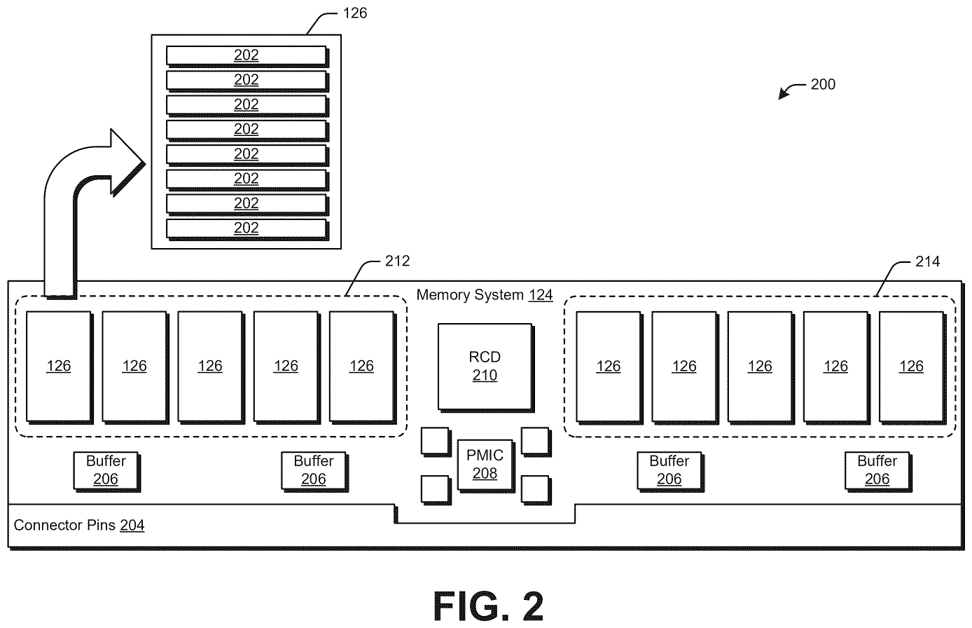

FIG. 2 is a block diagram of a non-limiting example 200 of a memory system. The illustrated example includes the memory system 124 having a plurality of the memory chips 126.

In one or more implementations, the memory system 124 is an in-line memory module, and each of the memory chips 126 is dynamic random-access memory (DRAM), such as synchronous dynamic random-access memory SDRAM. By way of example, the memory system 124 is a dual in-line memory module (DIMM). When configured as an in-line memory module, for instance, the memory system 124 includes the memory chips 126 (DRAMs) mounted communicably to a printed circuit board on one or both sides (i.e., front and/or back) of the printed circuit board. In one or more implementations, the memory system 124 is standardized, such that various aspects of the memory system 124 and/or the memory chips 126 conform to a standard, e.g., a JEDEC standard. Although ten memory chips 126 are depicted in the illustrated example, the memory system 124 can include any different integer number of memory chips 126 in accordance with the described techniques, e.g., two (2), eight (8), nine (9), twelve (12), fifteen (15), sixteen (16), twenty (20), twenty-four (24), twenty-seven (27), thirty (30), and so on.

In one or more implementations, at least one of the memory chips 126 includes a plurality of memory die 202, such as memory die arranged in a “stacked” or “3D” configuration. In connection with DRAM technology, such an arrangement may be referred to as “stacked DRAM,” “3D stacked DRAM,” or a “3D DRAM stack. ” Thus, in one or more implementations, at least one of the memory chips 126 is a stacked DRAM. This also means that each of the memory chips 126 may comprise a stack of memory die 202 in at least one variation. For example, each of the memory chips 126 is a stacked DRAM. Although the view of the memory chips 126 with the stack of memory die 202 includes eight memory die, in variations, any of the memory chips 126 may have a different integer number of memory die, e.g., four (4), five (5), ten (10), and so forth, without departing from the spirit or scope of the described techniques.

The memory system 124 also includes pins 204. The pins 204 serve as electrical connectors or contacts that are used to communicably link the memory system 124 to at least one other component of a system (e.g., of the system 100), allowing transfer over the link, for example, of data, address signals, power, control signals, command/address signals, and so on, between the memory system 124 and the rest of the system. In at least one implementation, the pins 204 electrically connect the memory system 124 to a motherboard or “host”. The pins 204 can include one or more of data transfer pins, address pins, power and ground pins, control pins, and error correcting code (ECC) pins, to name just a few. The memory system 124 may include varying integer numbers of the pins 204 arranged in various layouts (e.g., with double rows of pins, with offset pins, with notches or cutouts in the arrangement) and having any of a variety of shapes (e.g., rectangular, triangular, rounded rectangle, etc.), without departing from the described techniques. Additionally, the pins 204 may be formed of any of a variety of materials including, for example, gold and/or gold plating, which is a suitable conductor of electricity and is resistant to corrosion. In variations, one or more notches or cutouts may be present in the pins 204, e.g., on an outboard side of the memory system 124 resulting in a gap of space (not shown) between pins and/or on an inboard side of the memory system 124 resulting in a gap (not shown) filled with at least a portion of the printed circuit board (e.g., silicon and/or other components of a printed circuit board).

In this example, the memory system 124 is also depicted with buffer(s) 206, power management integrated circuit 208 (referred to as PMIC 208), and registered clock driver 210 (referred to as RCD 210). It is to be appreciated that in variations the memory system 124 includes different/additional components (e.g., one or more memory controllers), does not include one or more of the depicted and/or described components, includes different numbers of the depicted and/or described components (e.g., a different number of buffer(s) 206), and so on, without departing from the spirit or scope of the described techniques.

The buffer(s) 206 of the memory system 124 may include one or more types of buffers and/or buffers that perform any of a variety of functions for the memory system 124 (e.g., programmed to perform the different functions and/or configured in hardware to perform such different functions), such as data buffers, input buffers, output buffers, and so on. In one example, for instance, a buffer may be connected to two of the memory chips 126 on one side and to a system on chip (SoC) (e.g., the system 100) on the other side, enabling the memory chips 126 to communicate with the system in a time sequenced fashion. On a host side interface of the buffer to the system (e.g., an SoC), the buffer may effectively multiply a frequency up, doubling the bandwidth by having two devices (e.g., memory chips 126) on the other side of the buffer and supplying twice the data that is then serialized to the host (i.e., the system) at twice the speed.

In another example, a buffer may be programmed or otherwise configured to, in one direction of communication between the memory chips 126 (and/or one or more other components of the memory system 124) and one or more system components to which the memory system 124 is connected (e.g., a “host”), combine signals and/or data, and in an opposite direction of communication separate signals and/or data. For signals and/or data routed from the memory chips 126 to a host, for instance, at least one buffer(s) 206 may separate the signals and/or data for further transmission to the host. For signals and/or data routed in the opposite direction, e.g., from the host to the memory chips 126, though, the at least one buffer(s) 206 may combine the signals and/or data into one or more channels for further routing to the memory chips 126.

In one or more implementations, the memory system 124 is configured to support a multi-channel architecture, where the memory chips 126 are accessed over multiple channels of the architecture, e.g., over two or more channels. For example, a first group or cluster of the memory chips 126 is accessed over a first channel (e.g., Channel A), and a second group or cluster of the memory chips 126 is accessed over a second channel (e.g., Channel B). It is to be appreciated that the memory system 124 may support access over more than two channels, e.g., a third channel (e.g., Channel C), a fourth channel (e.g., Channel D), and so on.

While in some implementations an individual memory chip 126 is accessed over just one channel of the multiple channels (e.g., all the memory die 202 of the individual memory chip are accessed over the one channel), in variations, an individual memory chip 126 may be accessed over at least two of the multiple memory channels (e.g., a portion of the memory die 202 of the individual chip is accessed over a first channel and a different portion of the memory die 202 of the individual chip is accessed over a second channel). In at least one variation, the memory system 124 supports a combination of such access, such that a first set of the memory chips 126 (at least one memory chip) is accessed entirely by a first channel, a second set of the memory chips 126 (at least one memory chip) is accessed entirely by a second channel, and a third set of the memory chips 126 (at least one memory chip) is accessed by both the first channel and the second channel (i.e., split access). In one or more implementations, such split access may be handled by a buffer 206 that is configured to facilitate access to the appropriate memory die of the memory chips 126 with the split access, such as for memory reads and/or memory writes. One or more of the memory chips 126 may be configured for such split access in scenarios where the memory system 124 is configured for error correcting code (ECC) use, for example. It is to be appreciated that access via multiple channels to the memory chips 126 may be arranged in a variety of ways for different numbers of channels, and include, for instance, one or more memory chips 126 that are accessed entirely over just one of the multiple channels and one or more memory chips 126 that are accessed over at least two of the channels (e.g., over at least a first channel and a second channel), without departing from the described techniques.

The illustrated example is depicted with an indication of a first cluster 212 of the memory chips 126 and an indication of a second cluster 214 of the memory chips 126. In at least one implementation, the first cluster 212 of the memory chips 126 is accessed over a first channel (and via respective buffer(s) 206 and pins 204), and the second cluster 214 of the memory chips 126 is accessed over a second channel (and via respective buffer(s) 206 and pins 204). For instance, read and write accesses of the first cluster 212 of memory chips 126 are serviced over the first channel, while read and write accesses of the second cluster 214 of memory chips 126 are serviced over the second channel. In at least one variation, while the memory chips 126 are clustered into multiple clusters, the clustering may not correspond to channels over which the memory chips 126 are accessed. Instead, for instance, despite being physically clustered on a printed circuit board, each of the memory chips 126 may be accessed over multiple channels (e.g., two channels), where one or more of the memory die 202 of an individual memory chip are accessed over a first channel, and one or more other memory die 202 of that same induvial memory chip are accessed over at least one other channel.

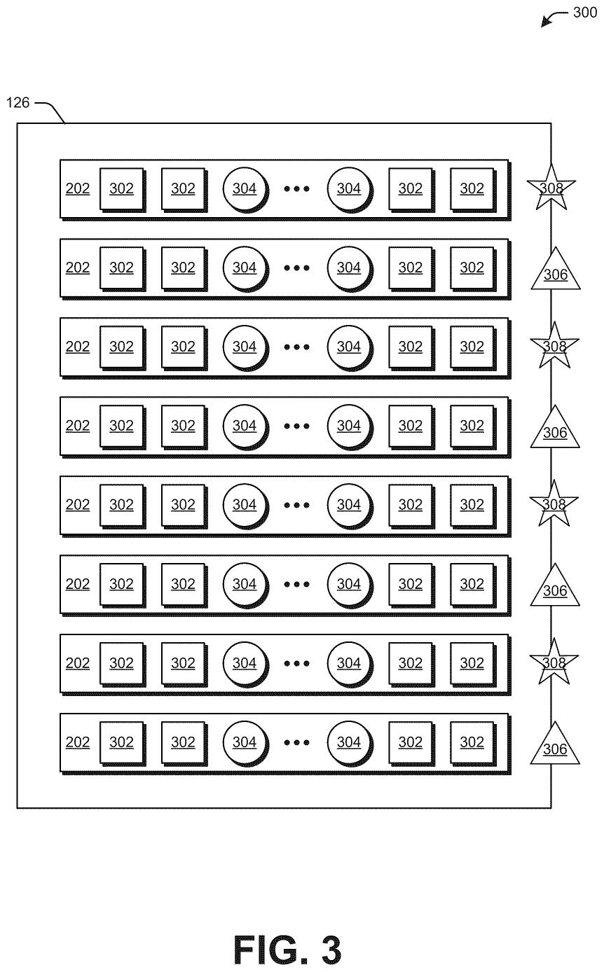

FIG. 3 is a block diagram of a non-limiting example 300 of pins of multiple memory die of a memory chip, such as of a stacked DRAM.

This figure depicts an example of one of the memory chips 126 having multiple memory die 202, such as when configured as a stacked DRAM. Here, each of the memory die 202 is shown with multiple types of pins 302, 304. As an example, the pins 302 correspond to data pins (DQ pins) and the pins 304 correspond to command/address pins (CA pins) of the memory die 202. In variations, the memory dies 202 may have different numbers of pins, e.g., more pins or fewer pins. Additionally or alternatively, the memory die 202 may include different and/or additional types of pins (or pins configured for different functionality), examples of which include data strobe (DQS) pins, data mask (DM) pins, clock (CK) pins, chip select (CS) pins, and any other pin types used with DRAM.

In one or more implementations, the data (DQ) pins are bidirectional lines that transmit data during read memory accesses and write memory accesses, such as with a data strobe pin (DQS pin) acting as a strobe signal that indicates when the data on the DQ pins is valid. In other words, the data (DQ) pins are part of a memory interface, which allows data to be transferred to and from memory, such as on edges of a clock signal. As part of a DDR interface, for instance, the data (DQ) pins allow data to be transferred in connection with memory access requests (e.g., memory reads and memory writes) on both the rising and falling edges of the clock signal, doubling the effective data rate. In connection with a read memory request, the memory die 202 send data stored therein out on the data (DQ pins), and the DQS signal indicates when the data is valid. In connection with a write memory request, a memory controller (e.g., a buffer within the memory chip 126 package or an external controller) sends data on the data (DQ) pins to be written to the memory die 202, and the DQS signal indicates when the data is valid for the memory die 202 to latch.

By way of contrast, command/address (CA) pins are electrical connections that carry commands and addresses to the memory die 202, enabling a memory controller (e.g., a buffer) to access specific memory locations and perform operations. For instance, the command/address (CA) pins allow a memory controller (e.g., a buffer) to select a memory location to access (e.g., bank, row, and/or column for DRAM) and select one or more operations to perform (e.g., read, write, etc.) at the selected memory location. Said another way, the command/address (CA) pins allow a memory controller to select a location, where data is read from or written to using the data (DQ) pins. Additionally or alternatively, the command/address (CA) pins are utilized in training procedures, such as command/address training mode, which optimizes the command/address bus for better signal stability and performance. In one or more implementations, command pins specify a type of command to perform (e.g., read, write, activate, precharge, etc.) while address pins specify the memory location, such as an address (e.g., row, column, bank).

The pins 302, 304 may be connected in a variety of ways to enable data to be read from and written to the memory die 202. In one or more implementations, the memory dies 202 belong to or are otherwise associated with ranks, e.g., rank zero (R0) or rank one (R1). Broadly, the ranks define a set of DRAM memory die that are connected to a same chip select and can therefore be accessed simultaneously. The illustrated example includes a first indication 306 and a second indication 308, which may represent a first rank (rank zero—R0) and a second rank (rank one—R1), respectively. In the illustrated example, the inclusion of these ranks indicates one possible division of the memory die 202 between the different ranks. In variations, the memory dies 202 may be divided differently among ranks. Alternatively or additionally, there may be a different number of ranks than two, such as one rank, three ranks, and so on.

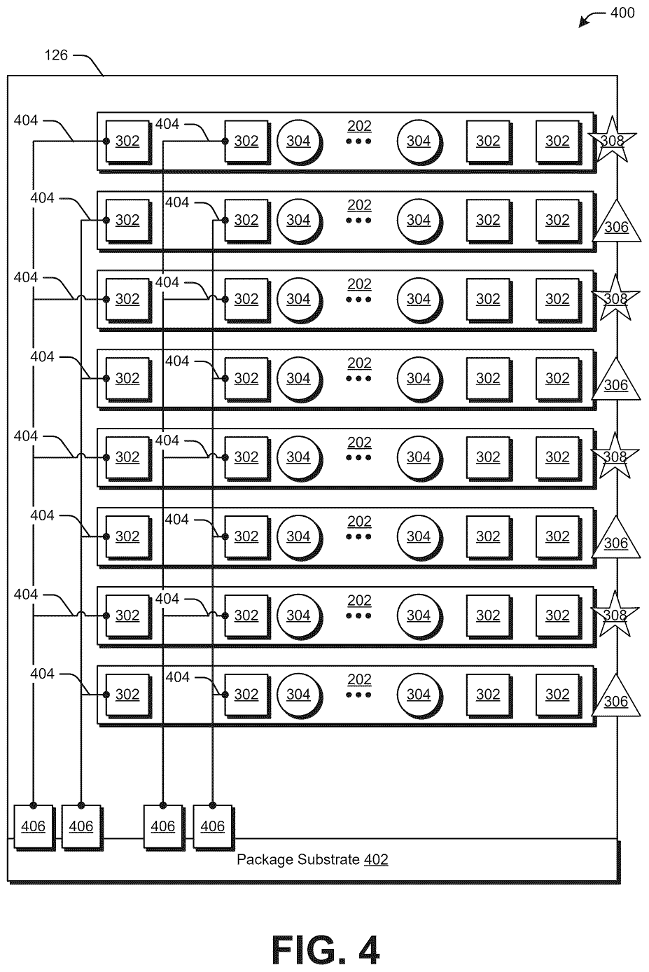

FIG. 4 is a block diagram of a non-limiting example 400 depicting how data (DQ) pins of multiple memory die of a memory chip are directly connected to a package substrate.

The illustration depicts an example of one of the memory chips 126 having multiple memory die 202, such as when configured as a stacked DRAM. Like in the example discussed above, each of the memory die 202 has a plurality of pins 302, 304. In this example, the pins 302 correspond to data (DQ) pins of the memory chip 126. Notably, each of the data (DQ) pins of a first column and second column of pins is connected (e.g., directly) to a package substrate 402 of the memory chip 126 via a respective interconnect 404. In at least one implementation, each data (DQ) pin of every memory die 202 is connected via a respective interconnect 404 to the package substrate 402. In at least one implementation, the interconnects 404 are connected to pins of the package substrate 402. Due to the individual connections, the described techniques may utilize twice as many pins of the package substrate as conventional approaches, since each data (DQ) pin is connected.

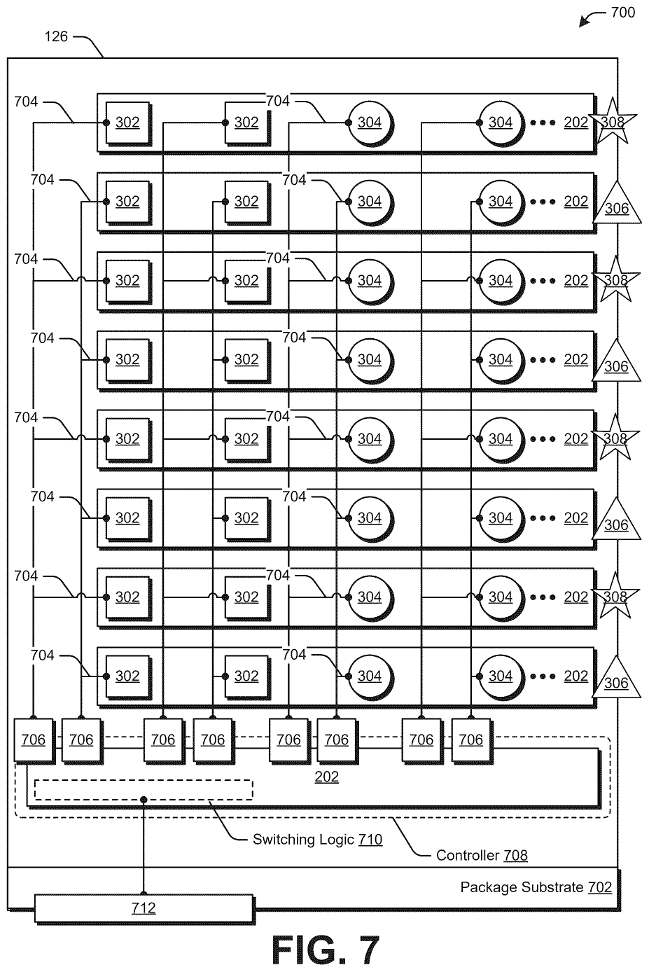

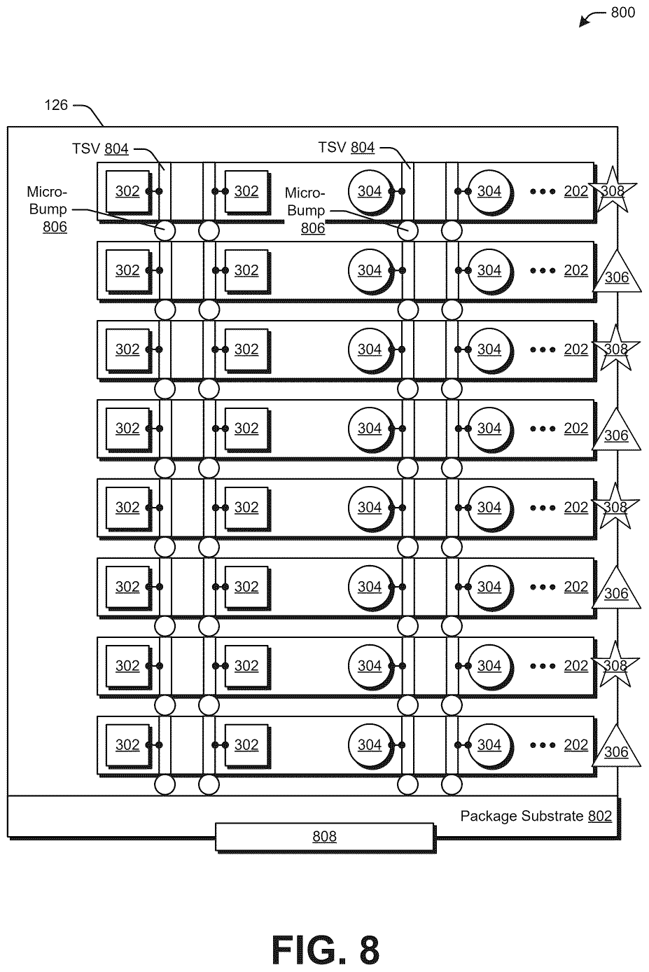

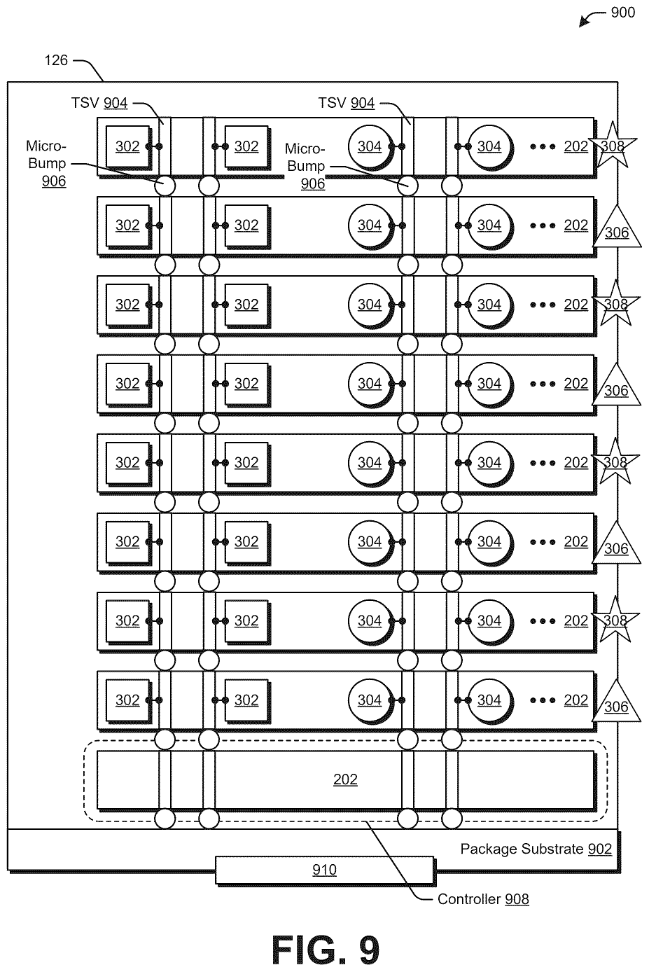

In at least one implementation, the interconnects 404 are bond wires, such that there is a bond wire connecting each data (DQ) pin of the memory chip 126 to the package substrate 402. Said another way, each data (DQ) pin is “bonded” to the package substrate 402. In at least one variation, one or more of the data (DQ) pins (e.g., all of them) are instead bonded externally at the printed circuit board level, e.g., externally to the printed circuit board of the memory system 124. The data (DQ) pins (and/or other pins) of the memory die 202 may be connected to the package substrate 402, and/or a buffer (or other component(s)) integrated between the pins and the package substrate 402 (e.g., a memory die of the memory chip 126), using any of a variety of connections in addition to or alternatively from bond wires, examples of which include but are not limited to micro bumps, flip-chip solder (e.g., C4) bumps, and copper to copper bonding, to name just a few. Examples of connecting the data (DQ) pins 302 and the command/address (CA) pins 304 of the memory die 202 to an intermediate component (e.g., another memory die 202), which serves as a controller to route signals to appropriate data (DQ) pins 302 and/or command/address (CA) pins 304, are discussed in relation to FIG. 7 and FIG. 9. Examples utilizing different types of connections to a package substrate (e.g., through silicon vias (TSVs) and micro bumps) are discussed in relation to FIG. 8 and FIG. 9.

In the illustrated example, the memory chip 126 is also depicted having data package entry points 406, e.g., ball grid array (BGA) balls. In one or more implementations, the data package entry points 406 serve as an interface between the memory chip 126 package and an external component, such as a printed circuit board (PCB) and/or memory system (e.g., memory module). In implementations where the data package entry points 406 are BGA balls, the BGA balls are mounted to the package substrate and act as a first contact point of the memory chip 126 package for data lines. Incoming and outgoing signals can be split and combined in any of a variety of ways (e.g., using a buffer and/or memory die 202 serving as a controller), enabling access to the data (DQ) pins 302 of the memory chip 126 individually. Due to this, a number of data package entry points 406 on the package substrate 402 can differ from a number of interconnects between the data (DQ) pins 302 and the package substrate 402 (and/or between the data (DQ) pins and an intermediate component serving as a controller). Although four data package entry points 406 are depicted, in at least one variation, a memory chip can include only one data package entry point without departing from the spirit or scope of the described techniques.

This connection scheme contrasts with conventional approaches where pairs of data (DQ) pins are connected to one another via short bond wires between memory die, such as where a data (DQ) pin of a first die associated with a first rank is connected with a short bond wire to a data (DQ) pin of a second, neighboring die associated with a second rank. In some conventional approaches, each of the data pins is paired with another data pin, such as by using a short bond wire, and then the data from the pair of data pins may be communicated externally at the printed circuit board level or to the package substrate. Rather than short bonds between pairs of data (DQ) pins, the data (DQ) pins of the memory chip 126 are individually connected with interconnects 404 forming long bonds (e.g., long bond wires) to the package substrate 402 or externally at the printed circuit board level.

As discussed in relation to FIG. 7 and FIG. 9 below, in one or more implementations, the memory chip 126 includes an intermediate component disposed within a package of the memory chip 126, at least in terms of electrical connectivity, between the data (DQ) pins and the command/address (CA) pins and the package pins or package entry points to route signals to the data (DQ) pins and/or the command/address (CA) pins individually. For instance, the interconnects 404 connect the data (DQ) pins and/or the command/address (CA) pins to the intermediate component, which is then connected to the package substrate 402 via any of a variety of connections, e.g., bond wires, pins, BGA balls, micro bumps, solder (e.g., C4) bumps, copper to copper bonding, and so on. Additionally or alternatively, the data (DQ) pins and/or the command/address (CA) pins of the memory die 202 are individually connected to such an intermediate component using any of a variety of connections, including but not limited to bond wires, micro bumps, pins, solder (e.g., C4) bumps, copper to copper bonding, and so forth.

In this configuration, the intermediate component may be programmable or otherwise configurable at the memory chip 126 package level to control use of the memory chip 126's data (DQ) pins and/or command/address (CA) pins in different manners rather than be controlled outside the package. As depicted in the illustrated examples, at least one of the memory die 202 (e.g., a DRAM base die in the stack) is configured to act like a controller to control and electrically isolate the data (DQ) signals and/or the command/address (CA) signals, e.g., rather than using a separate buffer between the memory die 202 and the package substrate 402. Alternatively or additionally, a compute unit may be used for this purpose. In at least one implementation, such an intermediate component, capable of controlling and/or electrically isolating such signals, is configured to handle respective clocking signals for the memory system 124, such as data strobe (DQS), write clock (WCK), and clock (CK). The DQS, WCK, CK, and/or whatever other data (DQ) or command address (CA) clocking mechanism may also be configurable in variations.

Multi-die memory chips with individually connected data (DQ) pins provide significant advantages over conventional approaches. In contrast to traditional stacked DRAM configurations where pairs of data pins from memory die having different ranks are connected together using short bond wires, the described architecture may connect each data pin for individual access to a package substrate of the memory chip or externally at the printed circuit board level, e.g., using long bond wires.

This individual connection scheme for data pins enables several key benefits. For example, it allows for increased flexibility in memory access configurations. The memory chip can be used, for instance, in a multiplexed (MUX) mode and/or an error correcting code (ECC) mode. Further, signal integrity is improved by eliminating the need for short bonds between die, which can introduce signal degradation. Memory bandwidth and system performance can also be enhanced by allowing separate access to each memory rank within the multi-die package.

As mentioned above, the memory chip comprises a plurality of memory die arranged in a stacked configuration, a package substrate, a plurality of data pins, and a plurality of command/address pins. Crucially, each data pin and each command/address pin is individually accessible through corresponding connections to the package substrate, or an intermediate controller within the package between the pins and the package substrate. Often, memory dies are separated into at least two ranks, with subsets of pins (e.g., data pins) associated with different ranks. By making the subsets of data pins individually accessible in the described architecture, the memory chip gains the flexibility to operate in various modes like multiplexed or error correcting code modes.

This architecture represents a departure from conventional systems where data pins are interconnected between dies. By providing individual connections to the package substrate (e.g., directly), the described approach overcomes limitations in flexibility and potential performance inherent in traditional stacked DRAM configurations. The result is a memory chip that offers greater versatility, improved signal integrity, and the potential for enhanced bandwidth and overall system performance.

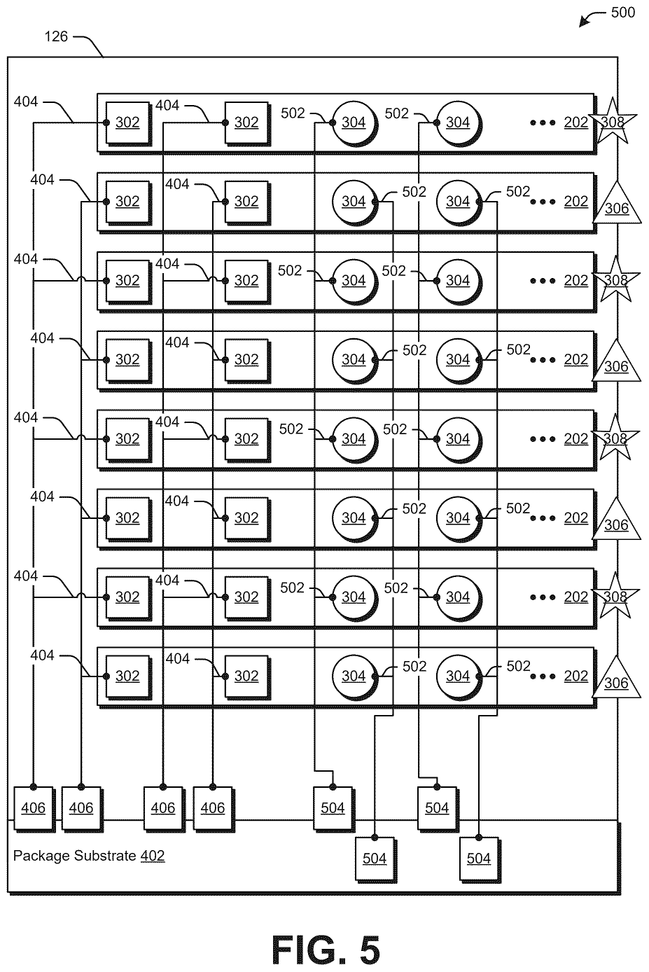

FIG. 5 is a block diagram of a non-limiting example 500 depicting how command/address (CA) pins of multiple memory die of a memory chip are directly connected to a package substrate.

Like FIG. 4 discussed just above, the illustrated example includes an example of one of the memory chips 126 having multiple memory die 202, such as when configured as a stacked DRAM. Like in the examples discussed above, each of the memory die 202 has a plurality of pins 302, 304. In this example, the pins 302 correspond to data (DQ) pins of the memory chip 126, and each of the pins 304 correspond to command/address (CA) pins. Notably, each of the data (DQ) pins of a first column of pins and a second column of pins is connected (e.g., directly) to a package substrate 402 of the memory chip 126 via an interconnect 404.

Additionally in this example, each of the command/address (CA) pins of the third column of pins and the fourth column of pins is connected (e.g., directly) to the package substrate of the memory chip 126 via an interconnect 502. In at least one implementation, each command/address (CA) pin of every memory die 202 is connected via a respective interconnect 502 to the package substrate 402. In at least one implementation, the interconnects 502 are connected to pins of the package substrate 402. Due to the individual connections, the described techniques may utilize twice as many pins of the package substrate as conventional approaches, since each command/address (CA) pin is connected.

In at least one implementation, the interconnects 502 are bond wires, such that there is a bond wire connecting each command/address (CA) pin of the memory chip 126 to the package substrate 402. Said another way, each command/address (CA) pin is “bonded” to the package substrate 402. In at least one variation, one or more of the command/address (CA) pins (e.g., all of them) are instead bonded externally at the printed circuit board level, e.g., externally to the printed circuit board of the memory system 124. The data (DQ) pins and/or the command/address (CA) pins of the memory die 202 may be connected to the package substrate 402, and/or a buffer (or other component(s)) integrated between those pins and the package substrate 402 (e.g., a memory die of the memory chip 126), using any of a variety of connections in addition to or alternatively from bond wires, examples of which include but are not limited to micro bumps, flip-chip solder (e.g., C4) bumps, and copper to copper bonding, to name just a few. As noted above, examples of connecting the data (DQ) pins 302 and the command/address (CA) pins 304 of the memory die 202 to an intermediate component (e.g., another memory die 202), which serves as a controller to route signals to appropriate data (DQ) pins 302 and/or command/address (CA) pins 304, are discussed in relation to FIG. 7 and FIG. 9. Examples utilizing different types of connections to a package substrate (e.g., through silicon vias (TSVs) and micro bumps) are discussed in relation to FIG. 8 and FIG. 9.

In the illustrated example, the memory chip 126 is also depicted having command/address package entry points 504, e.g., ball grid array (BGA) balls. In one or more implementations, the command/address package entry points 504 serve as an interface between the memory chip 126 package and an external component, such as a printed circuit board (PCB) and/or memory system (e.g., memory module). In implementations where the command/address package entry points 504 are BGA balls, the BGA balls are mounted to the package substrate and act as a first contact point of the memory chip 126 package for command/address lines. Incoming and outgoing signals can be split and combined in any of a variety of ways (e.g., using a buffer and/or memory die 202 serving as a controller), enabling access to the command/address (CA) pins 304 of the memory chip 126 individually. Due to this, a number of command/address package entry points 504 on the package substrate 402 can differ from a number of interconnects between the command/address (CA) pins 304 and the package substrate 402 (and/or between the command/address (CA) pins and an intermediate component serving as a controller). Although four command/address package entry points 504 are depicted, in at least one variation, a memory chip can include only one command/address package entry point without departing from the spirit or scope of the described techniques.

In some conventional approaches, command/address (CA) pins may be connected to one another via short bond wires between memory die, such as where a command/address (CA) pin of a first die associated with a first rank is connected with a short bond wire to a command/address (CA) pin of a second, neighboring die associated with a second rank.

The connection scheme described herein contrasts with these conventional approaches where all the dies of each memory chip are used for error correction code (ECC) with a single subchannel, because this connection scheme enables the die of an individual memory chip to be split between multiple subchannels to handle ECC. For instance, a memory chip having four memory die may be split for handling ECC such that two of the memory die are allocated to a first subchannel and the other two memory die are allocated to a second subchannel. This also allows memory manufacturers to produce memory chips (DRAM) having standard numbers of die, e.g., in powers of two.

Broadly, error correction code (ECC) is a method used in memory systems to detect and correct errors that may occur during data storage and retrieval processes. ECC works by adding redundancy to the data stored in memory chips, typically through additional bits that are calculated using the original data bits. These extra bits are known as parity bits. When data is written to a memory module, ECC algorithms generate parity bits based on the data bits and store them alongside the data. Later, when the data is read back, the ECC system recalculates the parity bits to determine if any errors have occurred during storage or transmission. If the recalculated parity does not match the stored parity, the ECC system can identify and correct errors in the data, often without any intervention from the system's processor.

This capability to detect and correct errors enhances the reliability of memory systems 124, particularly in environments where data integrity is critical, such as in servers, data centers, and systems handling critical applications. ECC is particularly valuable in addressing single-bit errors, which are the most common type of error in memory systems.

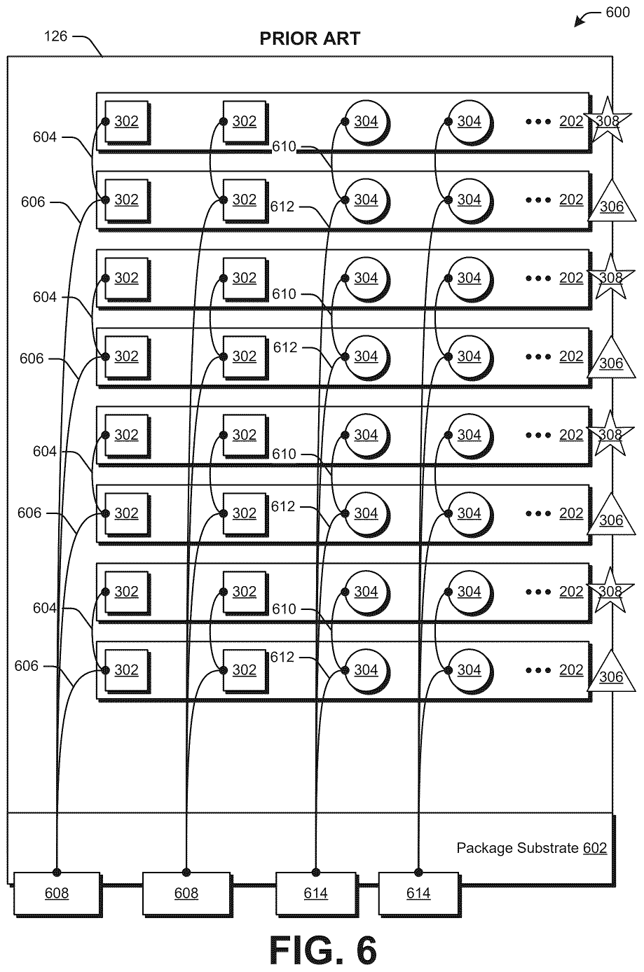

FIG. 6 depicts a prior art example 600 of connecting command/address (CA) pins of a multi-die memory chip to package entry points.

In the prior art example 600, the memory chip 126 includes multiple memory die 202 arranged in a stacked configuration on a package substrate 602. Each memory die 202 includes data pins 302 and command/address pins 304. The memory dies 202 are organized into different ranks, as indicated by the alternating first indications 306 and second indications 308 positioned along the right side of the illustration.

In this conventional approach, the data pins 302 are interconnected using short interconnects 604 that connect pairs of data pins between adjacent memory die 202 of different ranks. For example, a data pin 302 from a memory die 202 associated with a first rank is connected via a short interconnect 604 to a corresponding data pin 302 from a neighboring memory die 202 associated with a second rank. These short interconnects 604 may be implemented as short bond wires that create direct electrical connections between the paired data pins. Additionally, long interconnects 606 extend from the paired data pins to data package entry points 608 on the package substrate 602, routing the combined signals to external connection points.

Similarly, the command/address pins 304 are interconnected using short interconnects 610 between adjacent memory die 202 of different ranks, with long interconnects 612 routing the paired signals to command/address package entry points 614 on the package substrate 602. This conventional pairing approach limits individual access to both data and command/address pins.

Such prior art configurations limit flexibility in memory access because the paired command/address pins 304 cannot be accessed independently. When a memory access request is received, both command/address pins 304 in a pair are activated simultaneously, preventing individual control of command/address pins. Additionally, the short interconnects 610 between memory die 202 may introduce signal degradation and limit the potential for improved signal integrity. This conventional approach also restricts the ability to configure the memory chip 126 for different operational modes, such as switching between multiplexed and error correcting code modes, since the command/address pins are permanently paired through the short interconnects 610 and unable to be accessed individually.

FIG. 7 is a block diagram of a non-limiting example 700 depicting how command/address (CA) pins of multiple memory die of a memory chip are directly connected to a die serving as a controller for the memory chip.

In the illustrated example 700, the memory chip 126 includes multiple memory die 202 arranged in a stacked configuration on a package substrate 702. Each memory die 202 includes data pins 302 and command address pins 304. In one or more implementations, the memory dies 202 can be organized into different ranks as illustrated with the alternating first indications 306 and second indications 308.

In this implementation, each command/address pin 304 and each data pin 302 of the memory die 202 is connected to a controller 708 for individual access via corresponding interconnects 704. In at least one implementation, the interconnects 704 are bond wires that provide direct electrical connections between individual command/address pins 304, data pins 302, and controller connection points 706 on the controller 708. In variations, the interconnects 704 may be implemented using other types of connections, as described above and below.

Here, the controller 708 comprises an additional memory die 202 within the memory chip 126 package that serves as an intermediate component for routing command/address signals and data signals. For example, the controller 708 includes switching logic 710 that enables selective routing of command/address signals and data signals to and from individual command/address pins 304 and data pins 302 of the stacked memory die 202. In one or more implementations, the switching logic 710 is or includes multiplexer circuitry that can direct command/address signals and data signals from external sources to specific command/address pins 304 and data pins 302 during memory operations.

In one or more implementations, any of the memory dies 202 within the stacked configuration may be designated or configured to serve as the controller 708. For instance, a memory die 202 positioned at the bottom of the stack (such as a base die), in the middle of the stack, or at the top of the stack may be selected and programmed to function as the controller 708 with the switching logic 710. This flexibility allows the memory chip 126 to optimize performance based on specific design requirements or manufacturing considerations, as different memory die 202 positions within the stack may offer varying advantages for signal routing and thermal management.

In one or more implementations, the controller 708 connects to the package substrate 702 and communicates with external components through package entry points 712, e.g., data package entry points, command/address entry points, and/or entry points for combined data and command/address lines. This configuration allows the controller 708 to manage access to individual data pins 302 and individual command/address pins 304 independently, rather than accessing paired data pins and/or paired command/address pins simultaneously as in conventional approaches. The switching logic 710 may be programmable or configurable to support different operational modes, such as multiplexed mode or error correcting code mode, by selectively routing data and/or command/address signals to appropriate subsets of data pins 302 and/or command/address pins 304.

By utilizing the controller 708 with the switching logic 710, the memory chip 126 can provide flexible access to individual data pins 302 and command/address pins 304 while maintaining signal integrity through the individual interconnects 704. This approach enables independent control of data pins and command/address pins and supports various memory access configurations that may enhance system performance and bandwidth utilization.

FIG. 8 is a block diagram of a non-limiting example 800 depicting how command/address (CA) pins of multiple memory die of a memory chip are connected to a package substrate with through silicon vias and micro-bumps.

In the illustrated example 800, the memory chip 126 includes multiple memory die 202 arranged in a stacked configuration on a package substrate 802.

In this implementation, both the data pins 302 and the command/address pins 304 of the memory die 202 are connected to the package substrate 802 for individual access using through silicon vias 804 and micro bumps 806. The through silicon vias 804 extend vertically through the stacked memory die 202, providing electrical pathways that traverse through the silicon substrate of each die. These through silicon vias 804 enable direct electrical connections between data pins 302 on different layers of the stack and between command/address pins 304 on different layers of the stack and facilitate routing of signals through the vertical structure of the memory chip 126.

The micro bumps 806 serve as connection interfaces between adjacent memory die 202 and between the memory die 202 and the package substrate 802. In one or more implementations, the micro bumps 806 are small solder connections that provide mechanical support and electrical connectivity. The micro bumps 806 may be positioned at regular intervals across the surface of each memory die 202 to establish reliable connections with corresponding contact points on adjacent die or the package substrate 802, supporting both data and command/address signal paths.

The combination of through silicon vias 804 and micro bumps 806 enables each data pin 302 and each command/address pin 304 to be individually accessible through the package substrate 802, similar to the bond wire approach described in previous examples but using a different connection methodology. This TSV and micro bump configuration may offer advantages in terms of connection density, signal integrity, and manufacturing scalability compared to bond wire approaches for both data and command/address connections.

Package entry points 808 are positioned on the package substrate 802 to provide external connectivity for the memory chip 126. The through silicon vias 804 and micro bumps 806 route signals from individual data pins 302 and/or command/address pins 304 through the stacked configuration to these package entry points 808, enabling external access to each data pin 302 and each command/address pin 304 independently.

This configuration maintains the individual accessibility of data pins 302 and command/address pins 304 (e.g., from different ranks) while utilizing advanced packaging technologies. Additionally, this approach may enable higher connection densities and more compact package designs while preserving the flexibility benefits of individual data and command/address pin access, which is particularly valuable for supporting both multiplexed operations and error correction functionality.

FIG. 9 is a block diagram of a non-limiting example 900 depicting how command/address (CA) pins of multiple memory die of a memory chip are connected to a die serving as a controller for the memory chip with through silicon vias and micro-bumps.

In the illustrated example 900, the memory chip 126 includes multiple memory die 202 arranged in a stacked configuration on a package substrate 902. Similar to FIG. 8, this implementation uses through silicon vias 904 and micro bumps 906, but connects both the data pins 302 and command/address pins 304 to a memory die 202 configured as a controller 908 rather than directly to the package substrate.

In this example, the controller 908 comprises an additional memory die 202 within the memory chip 126 package that serves as an intermediate component for routing both data signals and command/address signals. In one or more implementations, similar to the controller 708 described in relation to FIG. 7, the controller 908 includes switching logic that enables selective routing of signals to and from individual pins of the stacked memory die 202. Alternatively, the controller 908 may be implemented using an additional or different type of component from a memory die. For example, a buffer or other dedicated logic component can serve as the controller 908, providing the same signal routing functionality while potentially offering different performance characteristics or manufacturing advantages.

This configuration combines the advanced packaging technologies of through silicon vias 904 and micro bumps 906 with signal routing capabilities of the controller 908, maintaining individual accessibility of all pins while offering improved connection density and signal integrity.

The controller 908 connects to the package substrate 902 and communicates with external components through package entry points 910. The through silicon vias 904 and micro bumps 906 route signals between the memory die pins and the controller 908, which then manages communication with the package entry points 910.

The controller 908 may be programmable to support different operational modes, such as multiplexed mode or error correcting code mode, by selectively routing signals to appropriate subsets of pins through the through silicon via 904 and micro bump 906 connections.

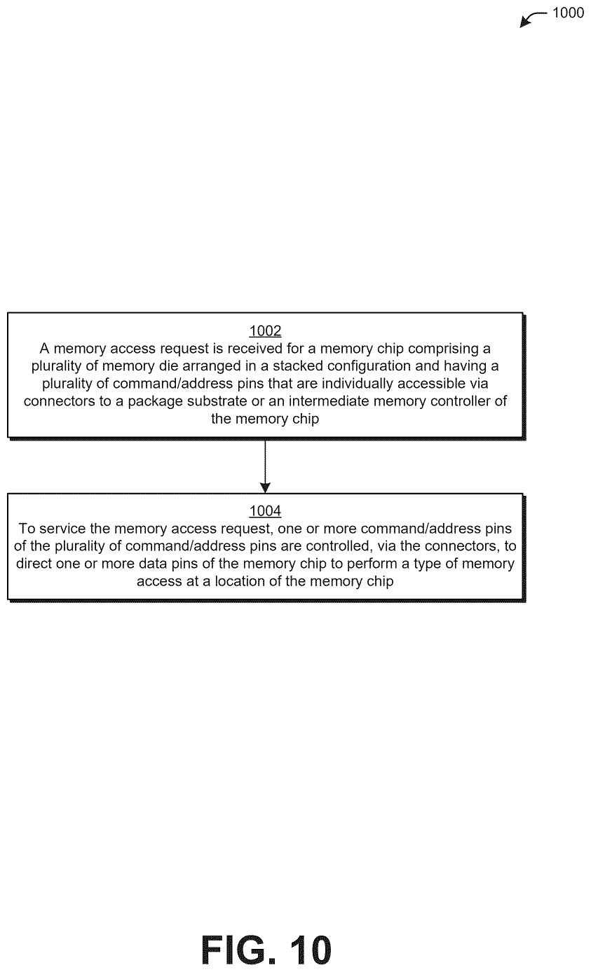

FIG. 10 depicts a procedure 1000 in an example implementation of a multi-die memory package with individually accessible command/address (CA) pins for use in error correction.

A memory access request is received for a memory chip (block 1002) In accordance with the principles discussed herein, the memory chip includes multiple memory die arranged in a stacked configuration and having multiple command/address pins that are individually accessible via interconnects to a package substrate or an intermediate controller of the memory chip. In one or more implementations, each command/address pin of the multiple command/address pins is individually connected to the package substrate or the intermediate controller via a respective interconnect, such as a bond wire.

By way of example, a memory access request is received for the memory chip 126. This memory access request may be for accessing the plurality of memory dies 202 of the memory chip 126. Examples of memory access requests that utilize the command/address (CA) pins include read requests, write requests, error correction code operations, precharge commands, activate commands, and so forth. As discussed above, the plurality of memory die 202 are arranged in a stacked configuration within the memory chip 126, and the plurality of command/address pins 304 are connected to the package substrate 402 or an intermediate controller (such as an intermediate memory die 202 serving as a controller) via interconnects 404, such that the command/address pins are individually accessible simultaneously.

To service the memory access request, one or more of the command/address pins are controlled, via the interconnects, to direct one or more data pins of the memory chip to perform a type of memory access at a location of the memory chip (block 1004). By way of example, one or more of the command/address pins 304 are controlled via the interconnects 502 to direct one or more of the data pins 302 to perform a specific type of memory access at a particular location within the memory chip 126. This control may involve sending command and address signals from the package substrate 402 or the intermediate controller to one or more of the memory dies 202 to specify the type and location of the memory access.

In scenarios where the memory access request is a read or write request, the controlled command/address pins 304 may specify a row, column, or bank of the memory chip 126 as the location for performing the memory access. The data pins 302 may then be directed to perform the read or write operation at the specified location. Alternatively, when the memory access request involves error correction, the command/address pins 304 may be controlled to enable error detection and correction operations across multiple memory die 202 or across multiple subchannels within the memory chip 126. This flexibility in controlling the command/address pins 304 allows for efficient handling of various memory operations, including error correction, leveraging the individual connections between each command/address pin 304 and the package substrate 402. The direct connections enable more precise control over memory operations and support advanced error correction techniques compared to conventional approaches.

It is to be appreciated that the figures are not drawn to scale in the illustrated examples, and the various shapes used in the figures to represent various components may differ (perhaps significantly) from the actual shapes of those components in implementation.

What is claimed is:

1. A memory chip, comprising:
a package substrate; and
a plurality of memory die arranged in a stacked configuration, the plurality of memory die having a plurality of command/address pins, wherein the plurality of command/address pins are individually accessible via interconnects to the package substrate or an intermediate controller.

2. The memory chip of claim 1, wherein the interconnects are bond wires.

3. The memory chip of claim 1, wherein the interconnects include through silicon vias and micro bumps.

4. The memory chip of claim 1, wherein each command/address pin of the plurality of command/address pins is individually connected to the package substrate or the intermediate controller via a respective interconnect.

5. The memory chip of claim 1, wherein the intermediate controller is a memory die of the plurality of memory die configured to control routing of commands and addresses to and from each of the plurality of command/address pins individually.

6. The memory chip of claim 5, wherein the memory die is further configured to isolate command/address signals and handle clocking signals including at least one of data strobe (DQS), write clock (WCK), or clock (CK) signals.

7. The memory chip of claim 1, wherein the plurality of command/address pins are individually controllable by a buffer external to the memory chip to enable the buffer to specify a type of a memory access and a location of the memory access in the memory chip.

8. The memory chip of claim 1, further comprising a plurality of data pins, wherein the plurality of data pins are individually accessible via interconnects to the package substrate or the intermediate controller.

9. The memory chip of claim 8, wherein the plurality of command/address pins are individually accessible to direct one or more data pins of the plurality of data pins to perform a type of a memory access at a location of the memory chip.

10. The memory chip of claim 9, wherein the type of the memory access is a read access or a write access at the location of the memory chip.

11. The memory chip of claim 9, wherein the plurality of command/address pins specify at least one of a row, column, or bank of the memory chip as the location for performing the memory access.

12. The memory chip of claim 8, wherein the intermediate controller is a memory die of the plurality of memory die configured to control routing of:
commands and addresses to and from each of the plurality of command/address pins individually; and
data to and from each of the plurality of data pins individually.

13. The memory chip of claim 1, wherein a first subset of command/address pins of the plurality of command/address pins are configured for use in a multiplexed mode of the memory chip and a second subset of command/address pins of the plurality of command/address pins are configured for use in an error correcting code mode of the memory chip.

14. The memory chip of claim 1, wherein the memory chip is a dynamic random-access memory (DRAM) package and the plurality of memory die are DRAM die.

15. A method comprising:
receiving a memory access request for a memory chip comprising a plurality of memory die arranged in a stacked configuration and having a plurality of command/address pins that are individually accessible via interconnects to a package substrate or an intermediate controller of the memory chip; and
controlling, via the interconnects, one or more command/address pins of the plurality of command/address pins to direct one or more data pins of the memory chip to perform a type of memory access at a location of the memory chip to service the memory access request.

16. The method of claim 15, wherein the memory access is a read access or a write access.

17. The method of claim 15, wherein controlling the one or more command/address pins to direct the one or more data pins comprises specifying at least one of a row, column, or bank of the memory chip as the location for performing the memory access.

18. The method of claim 15, wherein a memory controller controls the one or more command/address pins to direct the one or more data pins to perform the type of the memory access at the location of the memory chip.

19. A computing system, comprising:
a processor; and
a memory system communicatively coupled to the processor to service memory access requests of the processor, wherein the memory system includes a memory chip comprising:
a package substrate; and
a plurality of memory die arranged in a stacked configuration, the plurality of memory die having a plurality of command/address pins, wherein the plurality of command/address pins are individually accessible via interconnects to the package substrate or an intermediate controller of the memory chip.

20. The computing system of claim 19, wherein a first subset of command/address pins of the plurality of command/address pins are configured for use in a multiplexed mode of the memory chip to service the memory access requests of the processor and a second subset of command/address pins of the plurality of command/address pins are configured for use in an error correcting code mode of the memory system.
